(19) United States
(12) Patent Application Publication
(10) Pub. No.: US 2026/0029476 A1
(43) Pub. Date: Jan. 29, 2026

(54) SYSTEM AND METHOD FOR DETECTING BATTERY

(71) Applicant: Lite-On Technology Corporation, Taipei (TW)

(72) Inventors: Cing De Wu, Taipei (TW); Ming Wang Cheng, Taipei (TW)

(73) Assignee: Lite-On Technology Corporation, Taipei (TW)

(21) Appl. No.: 18/954,420

(22) Filed: Nov. 20, 2024

Related U.S. Application Data
(60) Provisional application No. 63/674,283, filed on Jul. 23, 2024.

(30) Foreign Application Priority Data
Oct. 15, 2024 (TW) 113139122

(51) Int. Cl. G01R 31/3842; G01R 31/36; G01R 31/392

(52) U.S. Cl. CPC G01R 31/3842; G01R 31/3648; G01R 31/392

(57) ABSTRACT

The present invention provides a system and a method for detecting a battery. The system includes the battery and a computation circuit. The computation circuit is electrically connected to the battery and is configured to measure the battery's parameters during a discharge process, and generate a parametric curve. The computation circuit also measures the battery's open-circuit voltage and generates an open-circuit voltage curve based on the open-circuit voltage. The computation circuit calculates a difference between the parametric curve and the open-circuit voltage curve, and determines the battery's state of health based on this difference.

### CROSS-REFERENCE TO RELATED APPLICATION

This application claims the priority benefit of U.S. Provisional Application Ser. No. 63/674,283, filed on Jul. 23, 2024 and Taiwan Application Serial Number 113139122, filed on Oct. 15, 2024. The entirety of each of the above-mentioned patent applications is hereby incorporated by reference herein and made a part of this specification.

### BACKGROUND

### Technical Field

The present disclosure relates to a system and method for detecting the state of health of a battery.

### Description of Related Art

With the rapid development of electric vehicles and energy storage systems, the importance of detecting battery State of Health (SoH) has become increasingly prominent. As the core component of these technologies, batteries directly affect the driving range of vehicles and the energy storage capacity of systems. Therefore, with the expansion of the electric vehicle market and the widespread adoption of energy storage systems, how to effectively evaluate and monitor the state of health of batteries has become a key factor in ensuring system stability and extending service life. Battery degradation not only reduces the driving range of electric vehicles but may also cause system performance decline, extended charging time, and even safety risks. Thus, through accurate battery health detection, vehicle owners and system managers may timely grasp the battery status, perform preventive maintenance, and ensure efficient system operation. Furthermore, with the development of battery health management technology, it may better support intelligent energy management, improve the overall energy utilization efficiency of the system, and promote the development of electric vehicles and energy storage systems in the field of sustainable energy.

### SUMMARY

The present invention proposes a battery detection system and a battery detection method, which may calculate the state of health of a battery according to the open-circuit voltage.

The present invention proposes a battery detection system, including a battery and a computation circuit. The computation circuit is electrically connected to the battery to measure a parameter of the battery during the discharge process of the battery to generate a parametric curve. The computation circuit also measures an open-circuit voltage of the battery and generates an open-circuit voltage curve according to the open-circuit voltage. The computation circuit calculates a difference between the parametric curve and the open-circuit voltage curve, and calculates the state of health of the battery according to this difference.

In an embodiment of the present invention, the aforementioned parameter include voltage, temperature, current or cumulative capacity, and the parametric curve is a voltage curve.

In an embodiment of the present invention, the aforementioned computation circuit measures the open-circuit voltage of the battery during a resting process, wherein this resting process is after the discharge process.

In an embodiment of the present invention, the aforementioned computation circuit adjusts a preset open-circuit voltage curve to the open-circuit voltage curve according to the open-circuit voltage.

In an embodiment of the present invention, the aforementioned computation circuit calculates multiple voltage differences between the voltage curve and the open-circuit voltage curve, and calculate an average of these voltage differences to serve as the difference.

In an embodiment of the present invention, the aforementioned computation circuit obtains power and temperature of the battery during the discharge process, and input the power, temperature, and difference into a function to obtain a value, and multiply this value by an initial state of health to obtain the state of health of the battery.

In an embodiment of the present invention, the state of health of the aforementioned battery may be calculated according to the following equation,

$${SOH}_{new} = {SOH}_{init} \times ( f ( T , P , Δ V ) + β )$$

where SOH_{new} is the state of health of the battery. SOHᵢₙᵢₜ is the initial state of health. T is temperature, P is power, ΔV is the difference, f( ) is a function, and β is a constant.

In an embodiment of the present invention, the aforementioned battery is charged during a charging process to reach a first state of health. If the difference between the first state of health and the aforementioned calculated state of health is greater than a threshold value, the computation circuit issues a warning message.

From another perspective, an embodiment of the present invention proposes a battery detection method, executed by a computation circuit. This battery detection method includes: measuring a parameter of the battery during a discharge process of the battery to generate a parametric curve; measuring an open-circuit voltage of the battery, and generating an open-circuit voltage curve according to the open-circuit voltage; and calculating a difference between the parametric curve and the open-circuit voltage curve, and calculating a state of health of the battery according to this difference.

In an embodiment of the present invention, the aforementioned battery detection method further includes: measuring the open-circuit voltage of the battery during a resting process, wherein the resting process is after the discharge process.

In an embodiment of the present invention, there is a waiting time between the aforementioned discharge process and the resting process. The electric potential of the battery during the waiting time is lower than the electric potential of the battery during the resting process.

In an embodiment of the present invention, the aforementioned battery detection method further includes: performing a micro-charging process after the waiting time and before the resting process, wherein the electric potential of the battery during the micro-charging process is raised from the electric potential of the battery during the waiting time to the electric potential of the battery during the resting process.

In an embodiment of the present invention, the aforementioned battery detection method further includes: adjusting a preset open-circuit voltage curve to the open-circuit voltage curve according to the open-circuit voltage.

In an embodiment of the present invention, the aforementioned battery detection method further includes: calculating multiple voltage differences between the voltage curve and the open-circuit voltage curve, and calculating an average of these voltage differences to serve as the difference.

In an embodiment of the present invention, the aforementioned battery detection method further includes: obtaining power and temperature of the battery during the discharge process, and inputting the power, temperature, and difference into a function to obtain a value, and multiplying the value by an initial state of health to obtain the state of health of the battery.

In an embodiment of the present invention, the aforementioned battery is charged during a charging process to reach a first state of health. The aforementioned battery detection method further includes: if the difference between the first state of health and the state of health is greater than a threshold value, issuing a warning message.

To make the aforementioned features and advantages of the present invention more apparent and understandable, exemplary embodiments are described below with detailed explanations in conjunction with the accompanying drawings.

### BRIEF DESCRIPTION OF THE DRAWINGS

FIG. 1 is a schematic diagram illustrating a battery detection system according to an embodiment.

FIG. 2 is a voltage curve diagram illustrating the charge and discharge program executed for state of health detection according to an embodiment.

FIG. 3 is a schematic diagram illustrating a parametric curve and an open-circuit voltage curve according to an embodiment.

FIG. 4 is a schematic diagram illustrating a preset open-circuit voltage curve according to an embodiment.

FIG. 5 is a schematic diagram illustrating voltage drops under different power levels according to an embodiment.

FIG. 6 is a schematic diagram illustrating the calculation of health status under different power levels according to an embodiment.

FIG. 7 is a flowchart illustrating a battery detection method according to an embodiment.

### DESCRIPTION OF THE EMBODIMENTS

Some embodiments of the present invention will now be described in detail with reference to the accompanying drawings. In the following description, when the same element symbols appear in different drawings, they will be regarded as the same or similar elements. These embodiments are only a part of the invention and do not disclose all possible implementations of the invention. More precisely, these embodiments are examples of the systems and methods in the scope of patent claims of this invention.

Regarding the terms “first”, “second”, etc. used in this document, they do not specifically indicate order or sequence. They are only used to distinguish elements or operations described with the same technical terms.

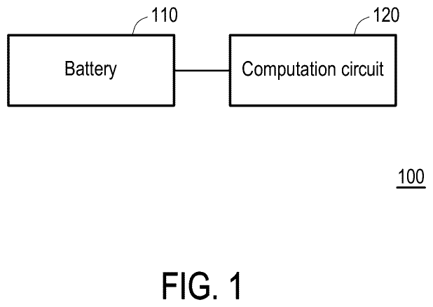

FIG. 1 is a schematic diagram illustrating a battery detection system according to an embodiment. Please refer to FIG. 1, a battery detection system 100 includes a battery 110 and a computation circuit 120. The battery 110, for example, is a battery pack which includes one or more cells. The types of these cells may be lithium-ion batteries, nickel-metal hydride batteries, solid-state batteries, sodium-ion batteries, etc. which are limited in the present disclosure. The computation circuit 120 is electrically connected to the battery 110. The computation circuit 120 may be a central processing unit, a microcontroller, an Application Specific Integrated Circuit (ASIC), a Programmable Logic Device (PLD), etc. In some embodiments, the computation circuit 120 may also be placed on a circuit board, and the circuit board is electrically connected to the battery 110. In some embodiments, the battery detection system 100 also includes multiple measurement units (not shown) including voltmeters, ammeters, power meters, temperature sensors, etc. The measured data will be transmitted to the computation circuit 120.

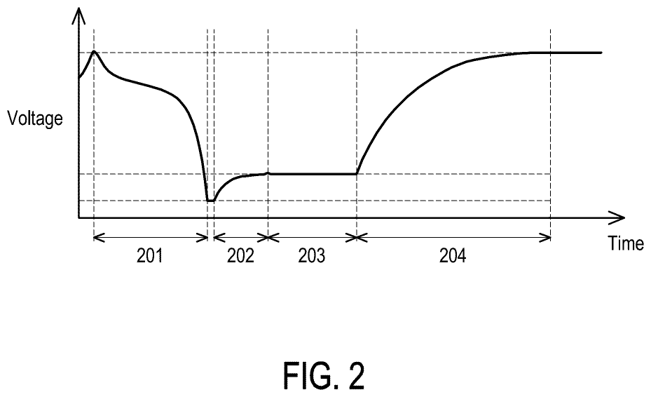

The computation circuit 120 performs health detection on the battery 110 periodically or irregularly. FIG. 2 is a voltage curve diagram illustrating the charge and discharge procedure executed for health detection according to an embodiment. Please refer to FIG. 2, the horizontal axis of this chart represents time, and the vertical axis represents voltage. Here, a discharge process 201, a micro-charging process 202, a resting process 203, and a charging process 204 are performed in sequence. During the discharge process 201, the battery 110 will be discharged, and the voltage of the battery 110 will gradually decrease. Multiple parameters of the battery 110 will be continuously measured during this discharge process 201, for example, including voltage, temperature, accumulated capacity and current. After the discharge process 201 ends, it will enter a waiting time to allow the internal state of the battery to reach a stable state, then proceed to the micro-charging process 202 until the state of charge (SOC) of the battery 110 reaches a preset percentage (for example, 30%). Next, the resting process 203 is performed to maintain the voltage of the battery at a fixed value, during which an open-circuit voltage (OCV) of the battery 110 is measured. In other words, there is a waiting time between the discharge process 201 and the resting process 203, and the electric potential of the battery 110 during this waiting time is lower than the electric potential of the battery 110 during the resting process 203. For example, the electric potential of the battery 110 during the waiting time is 40 volts, while the electric potential of the battery 110 during the resting process 203 is 43 volts. The micro-charging process 202 is performed after the waiting time and before the resting process 203, and the electric potential of the battery 110 during the micro-charging process 202 is raised from the electric potential of the battery 110 during the waiting time to the electric potential of the battery 110 during the resting process 203, for example, from 40 volts to 43 volts. Finally, the charging process 204 is performed to raise the state of charge of the battery 110 to the level before discharge.

The open-circuit voltage of the battery 110 is an important indicator for measuring the state of health of the battery. The state of health of the battery 110 is calculated based on this open-circuit voltage and the parameters measured during the discharge process 201.

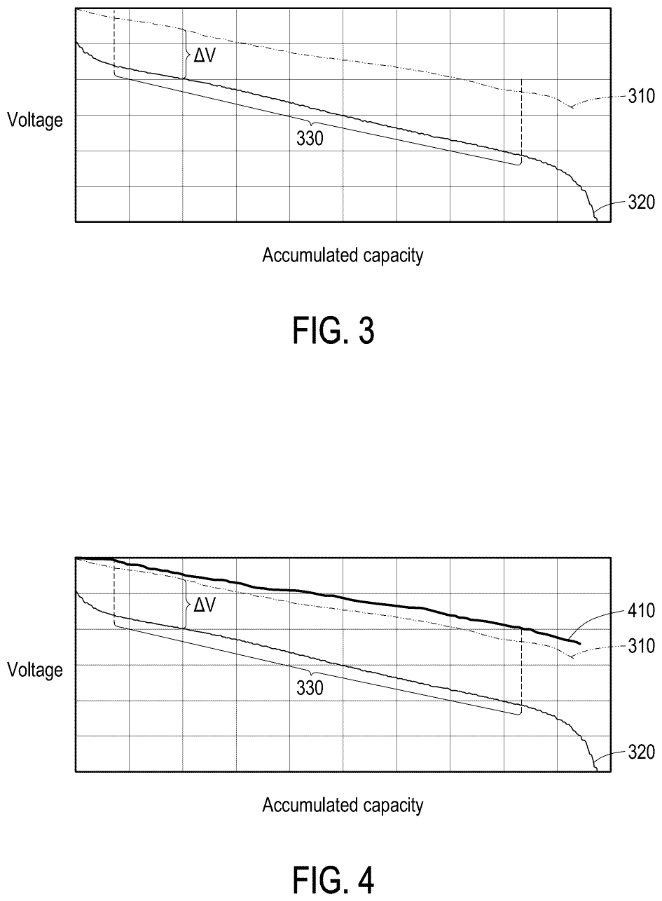

FIG. 3 is a schematic diagram illustrating a parametric curve and an open-circuit voltage curve according to an embodiment. Please refer to FIG. 2 and FIG. 3, the horizontal axis of FIG. 3 represents the accumulated (discharged) capacity during the discharge process 201, and the vertical axis represents voltage. The parametric curve 320 may be generated based on the parameters measured during the discharge process 201, for example, the parametric curve 320 is a voltage curve. In other embodiments, voltage, current, and/or temperature may also be input into an equation to obtain the parametric curve 320. On the other hand, the open-circuit voltage curve 310 may be generated based on the open-circuit voltage measured during the resting process 203. For example, the open-circuit voltage may be input into a battery model, and the open-circuit voltage curve 310 may be generated according to the internal resistance and other characteristics of the battery. Since the ambient temperature may also affect the battery characteristics, in some embodiments, the ambient temperature may also be input into the battery model along with the open-circuit voltage to generate the open-circuit voltage curve 310.

Next, a difference ΔV between the parametric curve 320 and the open-circuit voltage curve 310 is calculated, and this difference ΔV reflects the state of health of the battery 110. For example, when the battery 110 ages, the internal resistance of the battery would increase, and the difference ΔV between the parametric curve 320 and the open-circuit voltage curve 310 also increases. In other words, the difference ΔV is negatively correlated with the state of health of the battery 110. The state of health of the battery 110 is calculated according to this difference ΔV.

In some embodiments, the difference ΔV is measured within a charging range 330, for example, from 10% of SOC to 90% of SOC, but the invention is not limited to this. Multiple voltage differences (corresponding to different coordinates on the horizontal axis of FIG. 3) are calculated within the charging range 330. In some embodiments, the average of these voltage differences are calculated as the difference ΔV. Since the discharge power during the discharge process 201 may not be constant, and a fixed power is needed when calculating the state of health of the battery, multiple weights are determined according to the power, and then a weighted average of multiple voltage differences are calculated as the difference ΔV. Alternatively, only the voltage differences generated within a specific power range may be selected, and then the average is taken as the difference ΔV. Generally speaking, the larger the difference between the parametric curve 320 and the open-circuit voltage curve 310, the lower the state of health of the battery. Those skilled in the art may use any statistical method to measure the difference between the two curves. For example, two equations may be used to approximate the parametric curve 320 and the open-circuit voltage curve 310 respectively. These two equations may be polynomial functions but with different coefficients. Calculating the difference between the coefficients of the two equations may also generate the aforementioned difference.

FIG. 4 illustrates a schematic view of a preset open-circuit voltage curve according to an embodiment. Referring to FIG. 4, in some embodiments, upon completion of the production of battery 110, a corresponding open-circuit voltage curve (referred to as the preset open-circuit voltage curve 410) can be measured and set. When the battery 110 is initially manufactured, the difference between the preset open-circuit voltage curve 410 and the parametric curve 320 is calculated. However, as the battery ages, adjustments to the preset open-circuit voltage curve 410 are necessary. For example, based on the open-circuit voltage measured during the resting process 203, the preset open-circuit voltage curve 410 is adjusted to the open-circuit voltage curve 310, after which the difference ΔV between the parameter curve 320 and the open-circuit voltage curve 310 is calculated. This adjustment may involve translation, slope adjustment, or use of a lookup table to modify voltages along the horizontal axis. Generally, a decrease in the open-circuit voltage or an increase in the difference between the preset open-circuit voltage curve 410 and parametric curve 320 indicates battery aging, which can be addressed by shifting the preset open-circuit voltage curve 410 downward to generate the open-circuit voltage curve 310.

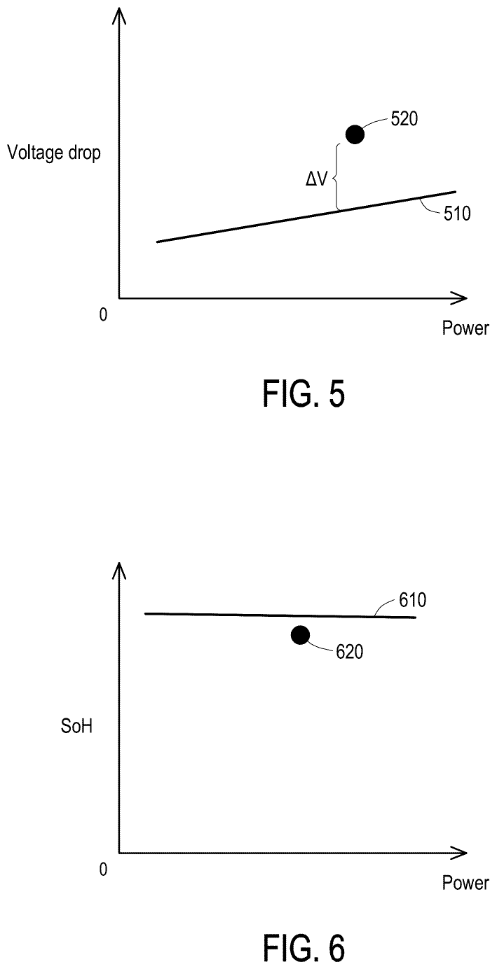

Here, the difference ΔV is evaluated from another perspective. FIG. 5 is a schematic diagram illustrating voltage drops at different power levels according to an embodiment. Please refer to FIG. 5, where the horizontal axis represents power and the vertical axis represents voltage drop. A curve 510 represents the open-circuit voltage drop during the discharge process as the power changes at a specific temperature, corresponding to the open-circuit voltage curve 310 in FIG. 3. On the other hand, the calculated difference ΔV is represented by a coordinate 520. The distance between the coordinate 520 and curve 510 represents the difference ΔV. When the distance between coordinate 520 and curve 510 is greater, it indicates a higher degree of battery aging.

In some embodiments, the power and temperature of the battery 110 during the discharge process 201 are obtained, and then this power, temperature, and the aforementioned difference ΔV are input into a function to obtain a value, which is then multiplied by an initial state of health to obtain the state of health of the battery 110. Specifically, the state of health may be calculated according to the following equation.

$${SOH}_{new} = {SOH}_{init} \times ( f ( T , P , Δ V ) + β ) \qquad [ Equation 1 ]$$

Where SOH_{new} is the state of health of the battery 110. SOHᵢₙᵢₜ is the initial state of health. T is the temperature, and P is the power. f( ) is a function which may include a linear function, polynomial function, exponential function, or logarithmic function. β is a constant, and different constants β may be set for different temperatures in some embodiments. The coefficients in the function f( ) and the constant β may be determined through experiments. In some embodiments, the difference ΔV and the output of the function f( ) may be negatively correlated, with a larger difference resulting in a smaller f(T,P,ΔV). This calculation may be represented as FIG. 6, where the horizontal axis represents power and the vertical axis represents state of health. A curve 610 represents the initial state of health SOHᵢₙᵢₜ, and a coordinate 620 represents the state of health SOH_{new} of the battery 110. The aforementioned value f(T,P,ΔV) is inversely proportional to the distance between the coordinate 620 and the curve 610, with a smaller value of f(T,P,ΔV) resulting in a greater distance.

After calculating the state of health SOH_{new}, this state of health SOH_{new} may be provided to the user for reference. The definition of state of health is current fully charged capacity divided by the initial fully charged capacity. Based on the state of health SOH_{new}, the fully charged capacity (FCC) can also be calculated. If the user's perception of the state of health is incorrect, they may mistakenly believe that the battery is not fully charged. For example, if the initial fully charged capacity is 1000 Ah, and the user believes the state of health is 90% (fully charged capacity is 900 Ah), but the actual state of health is 80%, then the fully charged capacity is only 800 Ah. In this situation, the user may think the battery is not fully charged. Through the aforementioned method, a real-time and accurate state of health can be calculated and provided to the user. In some embodiments, the aforementioned fully charged capacity may also be used to determine the cut-off point of the discharge process 201, and this fully charged capacity will be updated after each time the state of health is determined.

Battery discharge has a characteristic where the larger the load, the smaller the fully charged capacity; conversely, the smaller the load, the larger the fully charged capacity. In the calculation of the aforementioned Equation 1, power is also included as an input, therefore, the state of health can be accurately calculated for various loads.

On the other hand, the state of health SOH_{new} may also be used to determine whether to issue a warning message. If the battery 110 reaches a certain state of health (referred to as a first state of health) after the charging process. The computation circuit 120 calculates the difference between the first state of health and the state of health SOH_{new}. If this difference is greater than a threshold (for example, 10%, 20%, or 30%), a warning message is issued to the user or maintenance personnel.

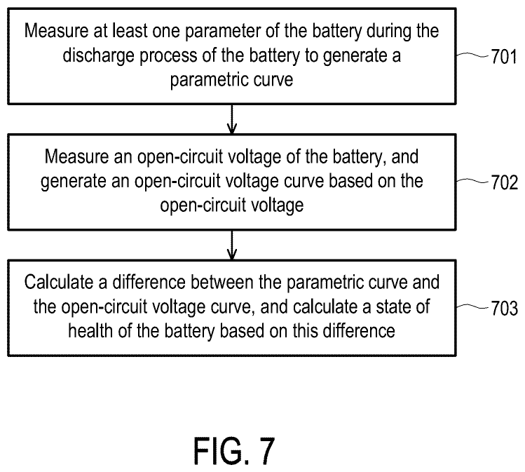

FIG. 7 is a flowchart illustrating a battery detection method according to an embodiment. Please refer to FIG. 7, in step 701, at least one parameter of the battery is measured during the discharge process of the battery to generate a parametric curve. In step 702, an open-circuit voltage of the battery is measured, and an open-circuit voltage curve is generated based on the open-circuit voltage. In step 703, a difference between the parametric curve and the open-circuit voltage curve is calculated, and a state of health of the battery is calculated based on this difference. Each step in FIG. 7 has been explained in detail as above, so the description will not be repeated here. It is worth noting that each step in FIG. 7 may be implemented as multiple codes or circuits, and the present invention is not limited to this. Furthermore, the method of FIG. 7 may be used in conjunction with the above embodiments or used independently. In other words, other steps may also be added between the steps of FIG. 7.

In the above-mentioned system and method, a difference is obtained after comparing the open-circuit voltage curve and the parametric curve. This difference reflects the state of health of the battery. Then, according to the equation disclosed above, a new state of health can be calculated, thereby providing accurate information or issuing warning messages in a timely manner.

Although the present invention has been disclosed by the above embodiments, it is not intended to limit the present invention. Any person skilled in the art may make some modifications and refinements without departing from the spirit and scope of the present invention. Therefore, the protection scope of the present invention should be defined by the appended claims.

What is claimed is:

1. A battery detection system, comprising:
a battery;
a computation circuit, electrically connected to the battery and configured to measure at least one parameter of the battery during a discharge process of the battery to generate a parametric curve,
wherein the computation circuit is configured to measure an open-circuit voltage of the battery, and generating an open-circuit voltage curve according to the open-circuit voltage,
wherein the computation circuit is configured to calculate a difference between the parametric curve and the open-circuit voltage curve, and calculating a state of health of the battery according to the difference.

2. The battery detection system as claimed in claim 1, wherein the at least one parameter comprises voltage, temperature, current or accumulated capacity, and the parametric curve is a voltage curve.

3. The battery detection system as claimed in claim 2, wherein the computation circuit is configured to measure the open-circuit voltage of the battery during a resting process, the resting process being after the discharge process.

4. The battery detection system as claimed in claim 2, wherein the computation circuit is configured to adjust a preset open-circuit voltage curve to the open-circuit voltage curve according to the open-circuit voltage.

5. The battery detection system as claimed in claim 4, wherein the computation circuit is configured to calculate a plurality of voltage differences between the voltage curve and the open-circuit voltage curve, and calculating an average of the voltage differences as the difference.

6. The battery detection system as claimed in claim 5, wherein the computation circuit is configured to obtain a power and a temperature of the battery during the discharge process, and inputting the power, the temperature, and the difference into a function to obtain a value, and multiplying the value by an initial state of health to obtain the state of health of the battery.

7. The battery detection system as claimed in claim 6, wherein the state of health of the battery is calculated according to a following equation,
$${SOH}_{new} = {SOH}_{init} \times ( f ( T , P , Δ V ) + β )$$
wherein SOH_{new} is the state of health of the battery, SOHᵢₙᵢₜ is the initial state of health, T is the temperature, P is the power, ΔV is the difference, f( ) is the function, and β is a constant.

8. The battery detection system as claimed in claim 1, wherein the battery is charged in a charging process to reach a first state of health,
if a difference between the first state of health and the state of health is greater than a threshold value, the computation circuit is configured to issue a warning message.

9. A battery detection method, executed by a computation circuit, the battery detection method comprising:
measuring at least one parameter of a battery during a discharge process of the battery to generate a parametric curve;
measuring an open-circuit voltage of the battery, and generating an open-circuit voltage curve according to the open-circuit voltage; and
calculating a difference between the parametric curve and the open-circuit voltage curve, and calculating a state of health of the battery according to the difference.

10. The battery detection method as claimed in claim 9, wherein the at least one parameter comprises voltage, temperature, current or cumulative capacity, and the parametric curve is a voltage curve.

11. The battery detection method as claimed in claim 10, further comprising:
measuring the open-circuit voltage of the battery during a resting process, the resting process being after the discharge process.

12. The battery detection method as claimed in claim 11, wherein there is a waiting time between the discharge process and the resting process, and an electric potential of the battery during the waiting time is lower than an electric potential of the battery during the resting process.

13. The battery detection method as claimed in claim 12, further comprising:
performing a micro-charging process after the waiting time and before the resting process, wherein an electric potential of the battery during the micro-charging process is raised from the electric potential of the battery during the waiting time to the electric potential of the battery during the resting process.

14. The battery detection method as claimed in claim 10, further comprising:
adjusting a preset open-circuit voltage curve to the open-circuit voltage curve according to the open-circuit voltage.

15. The battery detection method as claimed in claim 14, further comprising:
calculating a plurality of voltage differences between the voltage curve and the open-circuit voltage curve, and calculating an average of the voltage differences as the difference.

16. The battery detection method as claimed in claim 15, further comprising:
obtaining a power and a temperature of the battery during the discharge process, and inputting the power, the temperature, and the difference into a function to obtain a value, and multiplying the value by an initial state of health to obtain the state of health of the battery.

17. The battery detection method as claimed in claim 15, wherein the state of health of the battery is calculated according to a following equation,
$${SOH}_{new} = {SOH}_{init} \times ( f ( T , P , Δ V ) + β )$$
wherein SOH_{new} is the state of health of the battery, SOHᵢₙᵢₜ is the initial state of health, T is the temperature, P is the power, ΔV is the difference, f( ) is the function, and β is a constant.

18. The battery detection method as claimed in claim 9, wherein the battery charged in a charging process to reach a first state of health, the battery detection method further comprising:
issuing a warning message if a difference between the first state of health and the state of health is greater than a threshold value.
